(19) United States
(12) Patent Application Publication
(10) Pub. No.: US 2005/0121747 A1
(43) Pub. Date: Jun. 9, 2005

(54) Automatically passivated n-p junction and a method for making it

(76) Inventors: Jarek Antoszewski, Perth (AU); John Dell, Perth (AU); Charles Musca, Perth (AU); Lorenzo Faraone, Perth (AU); Brett Nener, Perth (AU); John Frank Siliquini, Perth (AU)

Correspondence Address: NIXON & VANDERHYE, PC, 1100 N GLEBE ROAD, 8TH FLOOR, ARLINGTON, VA, 22201-4714, US

(21) Appl. No.: 10/501,778

(22) PCT Filed: Jan. 17, 2003
(86) PCT No.: PCT/AU03/00048

(30) Foreign Application Priority Data
Jan. 17, 2002 (AU) PS0011

(51) Int. Cl. H01L 29/00; H01L 21/8238

(52) U.S. Cl. 257/553; 438/227

(57) ABSTRACT

An automatically passivated n-p junction is formed from a p-type body containing Group II and Group VI elements, one of which is mercury. A passivation layer is then formed having at least one window provided therein on a surface of the p-type body. The p-type body is then subjected to a reactive ion etching process using the passivation layer as a mask to form the n-p junction. Ohmic contacts are then formed on the n-type and p-type regions. The method may be extended to form an array of n-p junctions on a semiconductor body having a plurality of p-type material layers. This method comprises the further step of: etching the body to expose a portion of each layer; forming a passivation layer over the body; forming windows in the passivation layer; subjecting the body to a reactive ion etching process using the passivation layer as a mask to form an n-p junction in each layer or to form n-p junctions that extend substantially to the substrate; forming an ohmic contact to each of the n-type regions; and forming an ohmic contact to a common p-type layer or each layer of the portions. A semiconductor material comprising an n-p junction formed according to the aforementioned methods is also described, having a substrate, a layer of p-type material surmounting the substrate, a region of converted n-type material formed on a localised portion of the surface of the p-type material, so as to define an n-p junction between the p-type and the n-type material; a passivation layer surmounting the surface of the p-type material and the n-p junction, including windows respectively exposing part of the surface of the converted n-type material and a portion of the surface of the p-type material distant from the n-type material, such that ohmic contacts may be disposed on the exposed surface, without exposing the n-p junction.

### FIELD OF THE INVENTION

This invention relates to passivated n-p junctions in semiconductor materials, arrays formed of the same and a method or methods for producing passivated n-p junctions and arrays of the same. The invention has particular, but not exclusive, utility in the construction of infrared (IR) photodiodes and detectors that function as two-dimensional staring arrays fabricated using mercury cadmium telluride (HgCdTe).

Throughout the specification, unless the context requires otherwise, the word “comprise” or variations such as “comprises” or “comprising”, will be understood to imply the inclusion of a stated integer or group of integers but not the exclusion of any other integer or group of integers.

### BACKGROUND ART

Mercury cadmium telluride (MCT) n-on-p junctions are typically formed on p-type MCT using ion milling or ion implantation so as to form an n-type region.

Typically, a masking layer is formed on the surface of a p-type body of MCT. The masking layer has windows formed therein which expose the surface of the p-type body where the n-p junctions are to be formed. Ion implantation or ion milling is then performed to create the n-type regions, thus forming an n-on-p junction. However, the processes of ion implantation and ion milling both result in damage occurring to the MCT crystal lattice. In order to counter such damage, the MCT is annealed after forming the n-p junctions at high temperature. Annealing serves to repair the crystal lattice and/or activate the n-type regions. However, either or both ion implantation/milling and the annealing process tend to degrade the interface between the masking layer and the MCT, which results in degradation of the n-p junction surface and thus poor performance of the n-p junction. In order to overcome the above problem, the masking layer is commonly removed and the surface repassivated. However, this exposes the n-on-p junction at the surface to subsequent processing steps, which tend to also degrade the quality of the n-on-p junction. Although passivants have been used as part of a masking layer, the processes of ion milling and ion implantation and/or annealing affect the nature of the passivant such that after exposure to the ion implantation or ion milling and/or annealing process, the MCT/passivant interface is degraded. Thus, a new passivation layer needs to be formed.

Degradation of the n-on-p junction surface not only leads to a reduction in performance of the particular n-on-p junction, but also leads to variations in the performance of individual junctions within an array of junctions. Diode arrays formed using existing techniques can vary in performance criteria by as much as an order of magnitude across a wafer.

### DISCLOSURE OF THE INVENTION

In contrast with the prior art methods, the present invention provides a simpler process for producing automatically passivated n-p junctions, without utilising high temperature annealing, and in which the n-p junction at the surface is never exposed.

The present invention also provides for the construction of planar semiconductor arrays having multi-spectral characteristics that may function as IR photodiode detectors.

In accordance with one aspect of this invention, there is provided a method for forming an automatically passivated n-p junction, comprising the steps of: providing a p-type body containing Group II and Group VI elements, one of which is mercury; forming a passivation layer having at least one window provided therein on a surface of the p-type body; subjecting said p-type body to a reactive ion etching process using the passivation layer as a mask to form the n-p junction; and forming ohmic contacts to the n-type and p-type regions.

The lateral extension of the type conversion from p to n resulting from the reactive ion etching process, results in the n-on-p junction at the surface being under the passivation layer, resulting in an automatically passivated junction which is never exposed during subsequent processing. This, along with the lack of post-processing annealing, results in n-on-p junctions of superior quality and uniformity compared with existing techniques. The lack of post-processing annealing is due to the fact that n-on-p junctions formed by reactive ion etching do not require an activation anneal and do not suffer from the same degree of lattice damage caused by ion implantation/milling.

Preferably, the p-type body comprises mercury cadmium telluride.

Preferably, the step of forming a passivation layer with windows provided therein comprises the steps of forming a passivation layer on the p-type body and etching windows therein.

The passivation layer can be formed from any suitable material. Examples of suitable materials include ZnS, wider bandgap MeT and bi-layer passivants such as ZnS/Si₃N₄ or ZnS/SiO₂. Advantageously, the process doesn't degrade the performance of the passivant.

Preferably, the passivation layer is relatively thick to prevent type conversion of areas covered by the passivation layer. In this regard, a passivation layer thickness of 0.3 μm of ZnS has achieved good results. It is envisaged however that the passivation layer may be formed thinner than 0.3 μm and still provide good results, or that it may consist of a layer of two materials in which the upper layer is subsequently removed.

In accordance with a second aspect of this invention, there is provided an n-p junction formed in accordance with the method of the first aspect of this invention.

In accordance with a third aspect of this invention, there is provided a method for forming an array of n-p junctions on a semiconductor body having a plurality of p-type material layers containing Group II and Group VI elements, one of which is mercury, comprising the steps of:
etching the body to expose a portion of each layer;
forming a passivation layer over the body;
forming a window in the passivation layer in each portion;
subjecting the body to a reactive ion etching process using the passivation layer as a mask to form an n-p junction in each layer;
forming an ohmic contact to each of the n-type regions; and
forming an ohmic contact to a common p-type layer.

Preferably, the step of etching the body exposes a plurality of portions within each layer at spaced locations across the body, so as to form a plurality of multi-wavelength detectors.

Preferably, the method includes the step of etching a channel between adjacent detectors.

More preferably, the channel passes through all of the p-type layers except the common p-type layer.

In accordance with a fourth aspect of this invention, there is provided a method for forming an array of n-p junctions on a semiconductor body having a plurality of p-type material layers containing Group II and Group VI elements, one of which is mercury, comprising the steps of:
etching the body to expose a portion of each layer;
forming a passivation layer over the body;
forming a window in the passivation layer;
subjecting the body to a reactive ion etching process to form n-p junctions that extend substantially to the substrate;
forming an ohmic contact to each of the common n-type regions; and
forming ohmic contacts to each layer on said portions.

Preferably, the step of etching the body exposes a plurality of portions of each layer at spaced locations across the body to form a plurality of detectors.

Preferably, adjacent detectors are separated by an n-p junction.

In accordance with a fifth aspect of the present invention, there is provided a semiconductor material comprising an n-p junction, the material including:
a substrate;
a layer of p-type material surmounting said substrate;
a region of converted n-type material formed on a localised portion of the surface of said p-type material, defining an n-p junction between the p-type and n-type material;
a passivation layer surmounting the surface of the p-type material and the n-p junction, including windows respectively exposing part of the surface of the converted n-type material and a portion of the surface of the p-type material distant from the n-type material for disposing ohmic contacts on the respectively exposed surfaces, without exposing the n-p junction.

Preferably, the semiconductor material includes said ohmic contacts so as to form an electronically connectable component.

Preferably, said passivation layer is formed on the surface of the p-type material prior to conversion of the n-type material.

Preferably, said p-type material is MCT.

Preferably, said conversion is performed by a plasma induced process.

Preferably, said plasma induced process is a reactive ion etching process that creates a laterally displaced n-on-p junction beneath the surface of the passivation layer, without degrading the passivation layer.

Preferably, said passivation layer is formed of zinc sulphide (ZnS).

Preferably, said passivation layer has a thickness of 0.3 μm.

In a particular embodiment of this aspect of the invention, a layer of n-type material may be interposed between said substrate and said layer of p-type material so that said p-type layer surmounts said n-type layer, and said n-type layer surmounts said substrate so as to form a junction isolated n-on-p diode.

In this embodiment, preferably the region of n-type material extends through the p-type layer to the n-type layer.

Preferably, said region is annular, being arranged to circumscribe a portion of said layer of p-type material, isolating the circumscribed portion from the remainder of said layer of p-type material.

Preferably, a plurality of discrete regions of n-type material are provided in the layer of p-type material to form an array of n-p junctions therein, whereby a said window is disposed to expose a portion of said circumscribed portion of p-type material for disposing an ohmic contact thereon.

In another embodiment of this aspect of the invention, a multi-wavelength detector may be formed by interposing between the layer of p-type material and the passivation layer:
an isolating layer of p-type material;
a second layer of p-type material; and
another isolating layer of p-type material;
   whereby the isolating layer surmounts the first layer of p-type material, the second layer surmounts the isolating layer, the other isolating layer surmounts the third layer, and the passivation layer surmounts the other isolating layer.

Other layers such as a third layer and a further isolating layer may be interposed between the other isolating layer and the passivation layer in an accumulative manner to allow for the formation of additional wavelength detectors.

According to this embodiment, preferably the layers of p-type material are each formed of a thickness corresponding to a predetermined cut-off wavelength.

In order to function as a detector, the semiconductor material is arranged so that incident light impinges the substrate side thereof. In this arrangement, it is preferred that the thickness of each layer is such that the cut-off wavelength of the first layer is less than the second layer, and the second layer is less than any third layer and so on.

Preferably, the isolating layers are formed of semiconductor material having a wider band gap than the semiconductor material used for forming the p-type layers.

Preferably, the p-type layers and their surmounting isolating layers are arranged in pairs that are recessed such that a portion of each corresponding p-type layer and isolating layer pair constitutes the final layer pair of that portion of the semiconductor material and is surmounted by said passivation layer.

In one type of multi-wavelength detector, a said converted n-type region may be formed in each final layer pair and extends through the isolating layer to the layer of p-type material thereof; and said windows are provided in the passivation layer of each final layer pair to expose part of each converted n-type region for disposing said ohmic contacts thereon.

Preferably, a channel is formed extending through the outer layers of p-type material and the isolating material so that the passivation layer directly surmounts the first isolating layer at prescribed locations on the semiconductor material to divide the same into predetermined detector elements or pixels constituting the array. In this manner, the channel reduces cross talk between adjacent detector elements.

In another type of multi-wavelength detector, a said converted n-type region may be formed in each final layer pair comprising: (i) the first p-type layer and the corresponding surmounting isolating layer thereof, and (ii) the last p-type layer and the corresponding surmounting isolating layer thereof; whereby the converted n-type region extends through to the substrate, and said windows are provided in the passivation layer of: (i) said first and last final layer pairs to expose part of each converted n-type region, and (ii) each final layer pair distant from said converted n-type region to expose part of the isolating layer thereof; for disposing said ohmic contacts on the exposed parts of the semiconductor material.

In this manner, the converted n-type regions divide up the semiconductor material into predetermined detector elements or pixels constituting the array.

Preferably, in either type of multi-wavelength detector, each detector element comprises a single final layer pair from each of the layers constituting the semiconductor material, whereby each final layer pair is adjacent to another layer pair within said detector element.

### BRIEF DESCRIPTION OF THE DRAWINGS

The invention will now be described with reference to four embodiments thereof and the accompanying drawings, in which:

FIG. 1 shows a passivation layer and a photoresist layer provided on a p-type body, in accordance with the first embodiment of the invention;

FIG. 2 shows the formation of a window in the passivation layer of FIG. 1;

FIG. 3 shows the p-type body of FIG. 2 after being subjected to a reactive ion etching process;

FIG. 4 shows the p-type body of FIG. 3 after forming ohmic contacts;

FIGS. 4A to 4C show successive steps in forming a junction-isolated n-on-p diode according to the second embodiment of the invention; and

FIGS. 5 to 13 show successive steps in forming a multi-wavelength detector according to the third embodiment of the invention; and

FIGS. 14 to 19 show the steps in forming a multi-wavelength detector according to a fourth embodiment of the invention.

### BEST MODE(S) FOR CARRYING OUT THE INVENTION

The first embodiment is directed towards a method of forming an n-on-p junction.

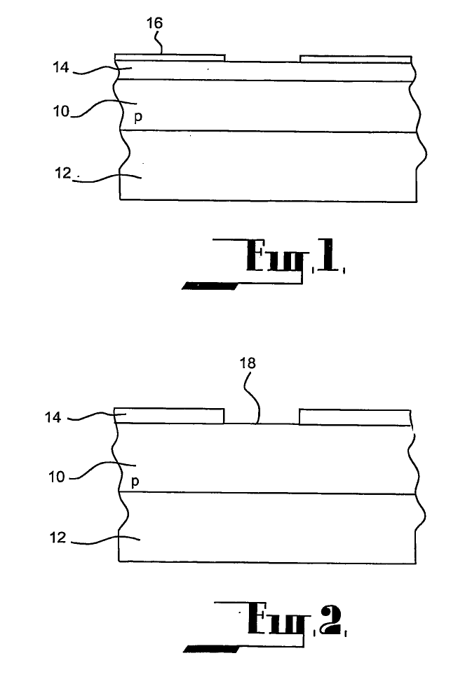

FIG. 1 shows a p-type body 10 of MCT provided on a substrate 12. Firstly, a passivation layer 14 of ZnS is formed on the p-type body 10 by thermal deposition. Other methods such as electron beam deposition may be used as appropriate.

Next, photoresist 16 is applied to the passivation layer 14. The photoresist 16 is selectively removed from the passivation layer 14 wherever a window is desired to be formed within the passivation layer.

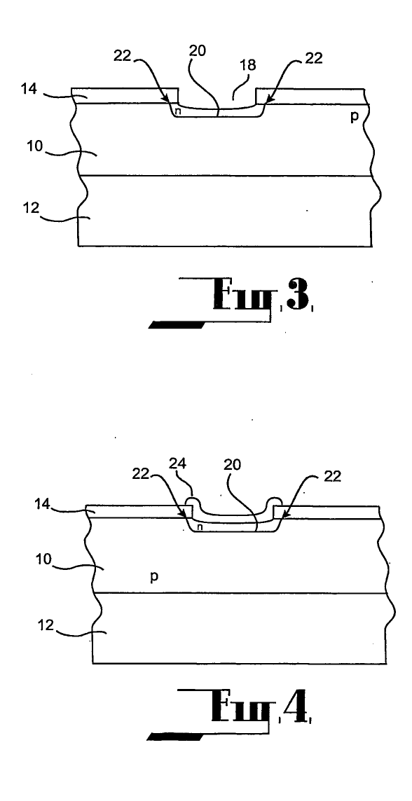

Windows 18 are then formed in the passivation layer 14 by etching through the removed photoresist 16, whereby regions of the passivation layer 14 not covered by the photoresist 16 are removed during the etching. The windows 18 extend to the surface of the p-type body 10. The photoresist 16 is then removed from the remaining passivation layer 14, as shown in FIG. 2.

Next, the exposed surface of the p-type body 10 is subjected to a reactive ion etching (RIE) process. This may be the same process that was used to etch windows 18 in the passivation layer 14. In the embodiment, a parallel plate reactor is used. The following conditions are used during the reactive ion etching process: hydrogen flow rate of 27 sccm; methane flow rate of 5 sccm; total pressure of 415 mTorr; DC bias of 200V; cathode temperature of 18° C. During the RIE process, the p-type body 10 and the substrate 12 are mounted on the RIE cathode.

The p-type body is then subjected to reactive ion etching for a period of 2 minutes. This results in the exposed surface of the p-type body 10 being etched to a depth of 0.4 μm, with type conversion from p-type to n-type occurring to a depth of approximately 3 μm in a region 20 adjacent to the exposed surface. Importantly, the lateral extension of the n-type region 20 results in the n-p junction 22 at the surface being beneath the passivation layer 14, resulting in an automatically passivated n-p junction.

Advantageously, it has been discovered that whilst reactive ion etching process parameters including time and total pressure can be used to control the depth of the n-p junction these do not significantly increase the width of the junction. As a result, by using this method of forming an n-on-p junction, it is possible to control the depth of the junction. If so desired, the n-on-p junction could extend to the substrate in order to reduce cross talk between adjacent n-on-p junctions.

Next, electrical contact to the n-type region 20 is made by depositing Cr/Au metal at 24. Electrical contact to the remaining p-type body can be formed in the usual manner.

It is to be noted that the process described in the present embodiment does not degrade the passivant/MCT interface, and does not require annealing to be performed after formation of the n-type region, which is believed to improve the quality and uniformity of the n-on-p junctions. In addition, the automatic passivation of the n-on-p junctions due to the n-on-p junction surface never being exposed, also assists in the quality and uniformity of the formed junctions.

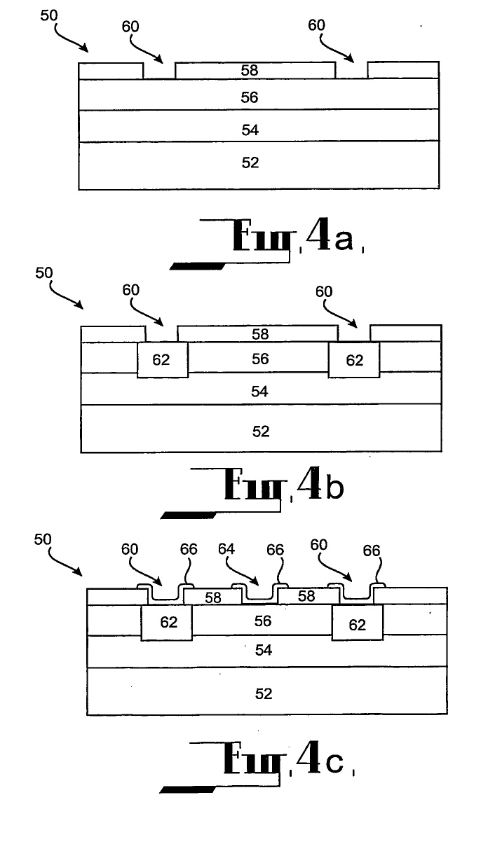

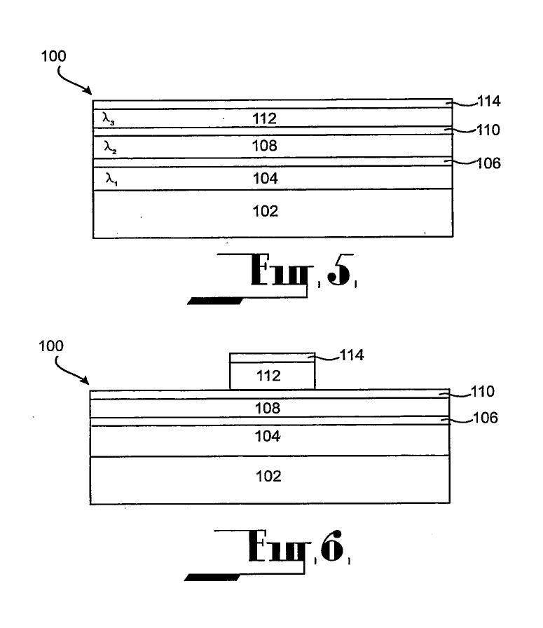

The second embodiment is directed towards a method of forming junction-isolated n-on-p diodes. The method is illustrated in FIGS. 4A to 4C. In this embodiment n-type regions are used to isolate p-type regions and form junction-isolated n-on-p diodes.

FIG. 4A shows a body 50 on which the junction-isolated n-p diodes are to be formed. The body comprises a substrate 52, on which the following layers are grown, in order:
a first layer of n-type material 54; and
a second layer of p-type material 56.

The layers 54 and 56 are formed from mercury cadmium telluride. A passivation layer 58 is then applied to the body 50. The passivation layer is formed of ZnS and in this particular embodiment is deposited to a thickness of 0.38 μm. Photoresist (not shown) is applied to the body 50 and photolithographically patterned. Windows 60 are then etched in the passivation layer 58. The result is shown in FIG. 4A.

Next, the body 50 is subjected to reactive ion etching in a similar manner to that described in the first embodiment. The reactive ion etching forms n-type regions 62 beneath each window 60. The process parameters of the reactive ion etching are controlled so as to ensure the n-type regions 62 extend to the n-type layer 54. As a result the portion of the p-type layer 56 between the n-type regions 62 is isolated from the remaining p-type layer 56 and forms an n-on-p junction therewith. The result is shown in FIG. 4B. It should be apparent that although FIG. 4B shows a cross-section of the body, the principle can be readily applied to form n-on-p junctions isolated in two dimensions by forming an n-type region 62 that encloses a portion of the p-type layer 56.

Photoresist (not shown) is then applied to the body 50 and photolithographically patterned. A window 64 is then etched in the passivation layer 58 above the isolated portion of the p-type layer 56. Next, metal contacts 66 are attached to the n-type regions 62 and to the isolated portion of the p-type region 56. The result is shown in FIG. 4C.

The third embodiment is directed towards a method of forming a multi-wavelength detector. The steps in the method are illustrated in FIGS. 5 to 16. The. embodiment will describe a method for forming a detector responsive to three wavelengths, λ₁, λ₂ and λ₃.

FIG. 5 shows a body 100 on which the detectors are to be formed. The body comprises a substrate 102, on which the following layers are grown, in order:
a first layer of p-type material 104;
an isolating layer of p-type material 106;
a second layer of p-type material 108;
another isolating layer of p-type material 110;
a third layer of p-type material 112; and
a final isolating layer of p-type material 114.

The layers 104, 108 and 112 of p-type material are formed from mercury cadmium telluride and are designed so as to have cut-off wavelengths of λ₁, λ₂ and λ₃, respectively.

In this embodiment, the detector will be used with light incident upon the substrate 102, and accordingly the cut-off wavelengths are chosen such that λ₁<λ₂<λ₃.

The isolating layers 106, 110 and 114 are also formed from MCT, however they are such that their band gaps are wider than those of the MCT layers 104, 108 and 112.

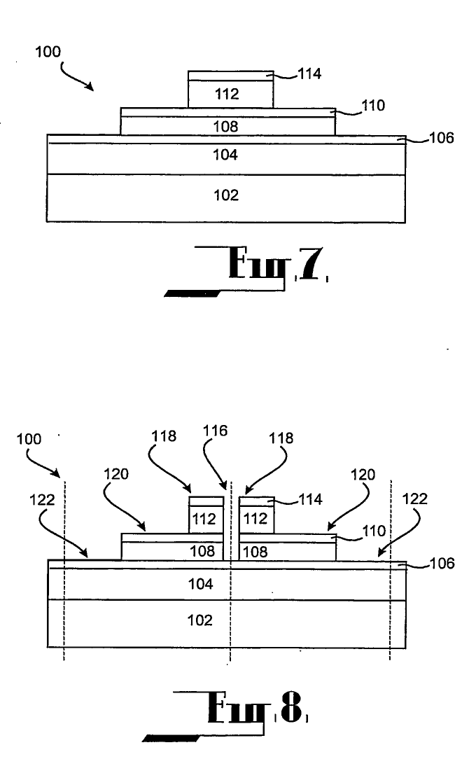

First, a mask is applied using a layer of photoresist. The mask is then photolithographically patterned. Next, the body 100 is etched in order to remove the isolating layer 114 and the third layer 112 in specific locations as determined by the patterning. The remaining photoresist is then removed. The result is shown in FIG. 6.

Next, a mask of photoresist is again applied to the body 100 and photolithographically patterned. The body 100 is then etched so as to remove the isolating layer 110 and the second layer 108 where it is not required. The photoresist is then removed. The result is shown in FIG. 7.

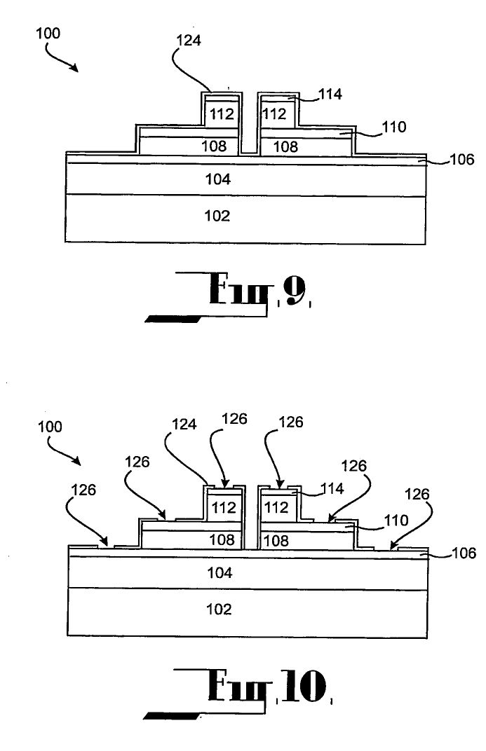

Next, a further mask of photoresist is applied and photolithographically patterned. The body 100 is then etched so as to form a channel 116 extending through the second and third layers 108 and 112 and the isolating layers 110 and 114. The channel 116 reduces cross talk between adjacent detectors. The result is shown in FIG. 8, wherein the dashed lines indicate adjacent detectors. Note that each detector has a portion 118 of the third layer 112 or 114 exposed, a portion 120 of the second layer 108 or 110 exposed and a portion 122 of the first layer 104 or 106 exposed.

Next, a passivation layer 124 is applied to the body 100. The passivation layer is formed of ZnS and in this particular embodiment is deposited to a thickness of 0.3 μm. The result is shown in FIG. 9.

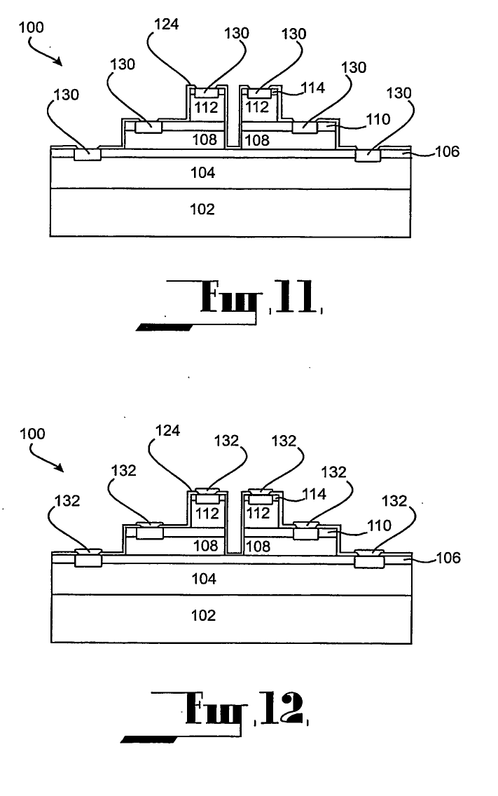

Next, photoresist is applied to the body 100 and photolithographically patterned. Windows 126 are then etched into the passivation layer 124. A window 126 is then formed on each of the portions 118, 120 and 122 on each pixel. The result is shown in FIG. 10.

Next, the body 100 is subjected to reactive ion etching in a similar manner to that described in the first embodiment. The reactive ion etching forms n-type regions 130 beneath each window 126. The n-type regions 130 formed on each of the portions 118, 120 and 122 serve to form n-p junctions with layers 112, 108 and 104, respectively in each detector. The result is shown in FIG. 11.

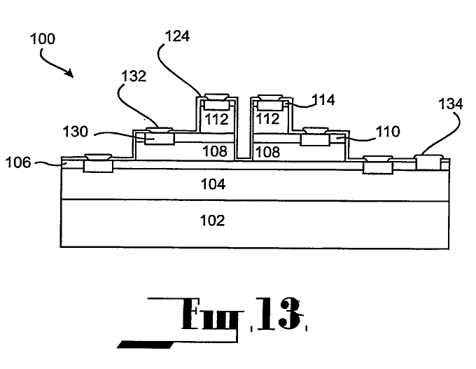

Next, a metal ohmic contact 132 is attached to each of the n-type regions 130. The result is shown in FIG. 12.

The final step is to attach a metal ohmic contact to the p-type region 104, which is a common p-type region in the embodiment. The metal contact is denoted 134 as shown in FIG. 13. By utilising the method for forming an n-on-p junction of the invention, the n-on-p junctions formed between the n-type regions 130 and the layers 104, 108 and 112 are automatically passivated. This provides a more consistent n-on-p junction which results in a more uniform detector. This is particularly important where an array of detectors are produced in a single body.

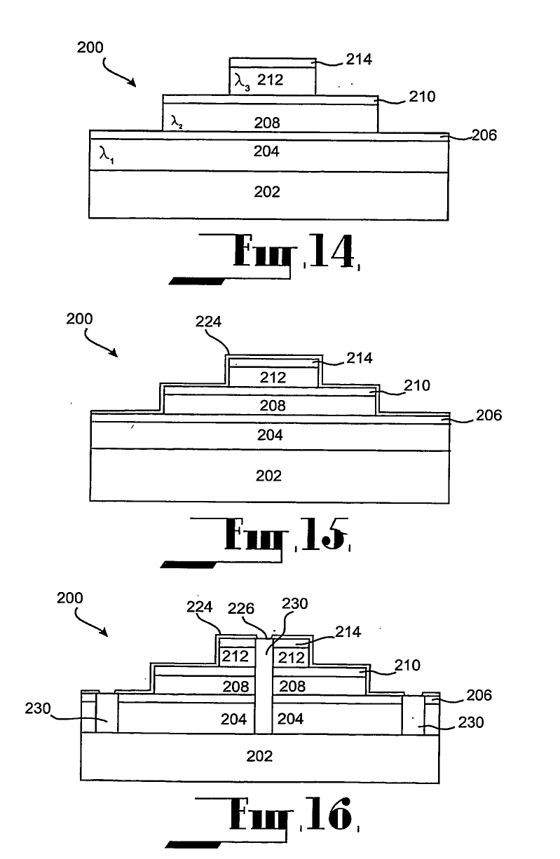

The fourth embodiment is also directed towards a method for producing a multi-wavelength detector capable of detecting three wavelengths. The fourth embodiment makes use of a body 200 of the same form as the third embodiment and like parts in the fourth embodiment use the same reference numerals as those in the third embodiment with 100 added thereto. Thus, the body 102 in the third embodiment is designated 202 in the fourth embodiment. The method of the fourth embodiment is illustrated in FIGS. 14 to 18.

The first steps of the embodiment are to etch the layers 212 and 208 in a similar manner to that described in the third embodiment. After the layers 212 and 208 have been etched, the body 200 will be as shown in FIG. 14.

Next, a passivation layer 224 is formed on the body 200. The passivation layer 224 is also made from ZnS and deposited to a depth of 0.3 μm. The result is shown in FIG. 15.

Next, photoresist is applied on top of the passivation layer 224 and photolithographically patterned. The passivation layer 224 is then etched to reveal windows 226.

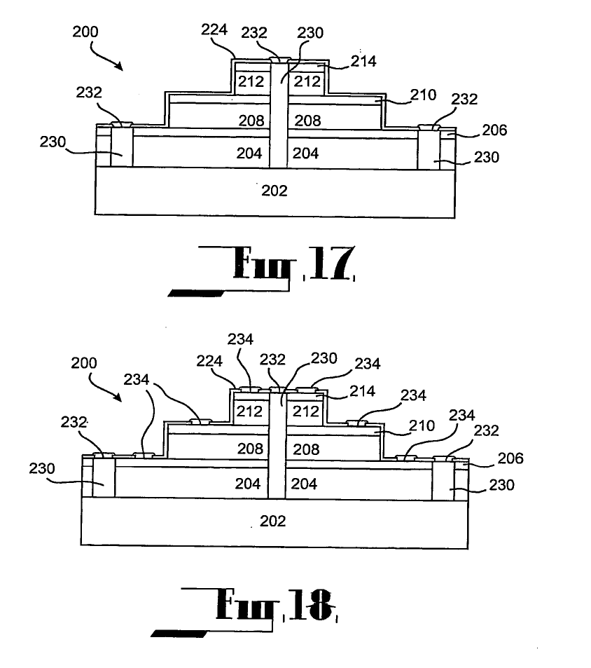

In contrast to the third embodiment, where a window 116 was formed in each of the portions 118, 120 and 122, in this embodiment the windows are formed at the boundaries between adjacent detectors. The body is then subjected to reactive ion etching for sufficient time for the n-type regions 230 to extend to the substrate 202. The result is shown in FIG. 16.

Next, metal contacts 232 are attached to each of the n-type regions 230. This result is shown in FIG. 17. The n-type regions 230 form horizontal n-on-p junctions with each of the layers 212, 208 and 204 in each detector.

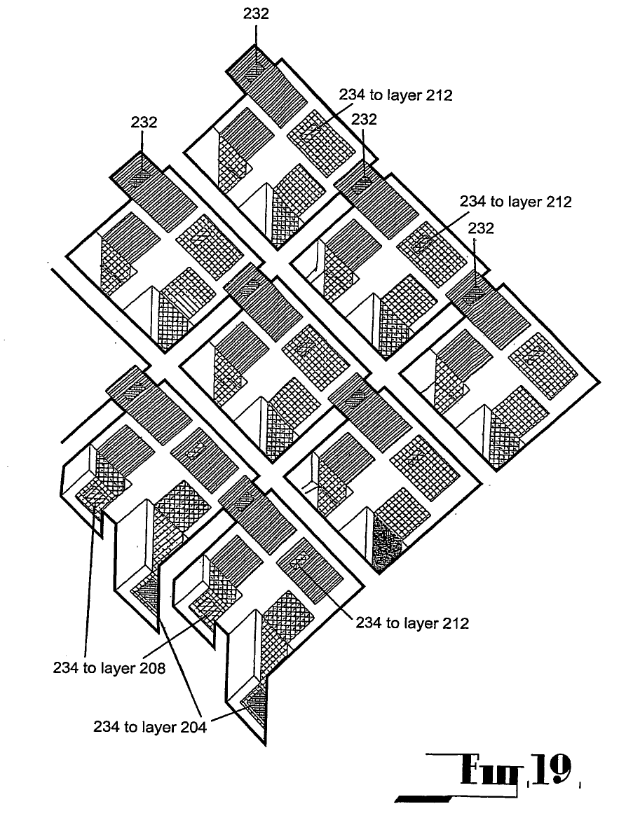

The final step is to form a metal contact 234 to the p-type region in each portion 218, 220 and 222 of each detector. The result is shown in FIG. 18.

FIG. 19 shows an example of arranging a plurality of detectors of the fourth embodiment as an array on a single body. The metal contacts 232 and 234 shown in FIG. 19 provide convenient access to the regions 230 and layers 212, 208 and 204. Each metal contact 232 and 234 is shown using two forms of hatching in FIG. 19, although it should be appreciated that the contact will be formed as a contiguous element. The cross-hatching represents the portion of the metal contacts 232 and 234 that extend to the region 230 or layer 212, 208 or 204 as appropriate. The single hatching represents the remainder of the metal contact 232 or 234, which provides a larger working area. Further, the remainder of the metal contacts 234 to layers 208 and 204 allow the metal contact to extend onto the same surface as the metal contacts to the region 230 and layer 212.

A similar arrangement may be adopted in order to produce a plurality of detectors of the third embodiment as an array on a single body.

It should be appreciated that this invention is not limited to the particular embodiments described above.

1. A method for forming an automatically passivated n-p junction, comprising the steps of:
providing a p-type body containing Group II and Group VI elements, one of which is mercury;
forming a passivation layer on a surface of the p-type body, said passivation layer having at least one window provided therein to expose a portion of the surface thereof through the passivation layer;
subjecting the exposed portion of the surface of said p-type body to reactive ion etching using the passivant layer as a mask to form the n-p junction, whereby the portion of the n-p junction at the surface of the p-type body is disposed beneath said passivation layer; and
forming ohmic contacts to the n-type and p-type regions.

2. A method as claimed in claim 1, wherein the p-type body comprises mercury cadmium telluride.

3. A method as claimed in claim 1, wherein the step of forming a passivation layer with windows provided therein further comprises the steps of:
forming a passivation layer on the p-type body; and
etching windows therein.

4. A method as claimed in claim 1, wherein the passivation layer has a thickness of 0.3 μm or less.

5. A method as claimed in claim 1, wherein the passivation layer comprises ZnS.

6. A method as claimed in claim 1, wherein the passivation layer comprises a first material underlying a second material wherein the second material is subsequently removed.

7. An n-p junction formed according to the method as claimed in claim 1.

8. A method for forming an array of n-p junctions on a semiconductor body having a plurality of p-type material layers containing Group II and Group VI elements, one of which is mercury, comprising the steps of:
etching the body to expose a portion of each layer;
forming a passivation layer over the body;
forming a window in the passivation layer in each portion;
subjecting the body to a reactive ion etching process using the passivation layer as a mask to form an n-p junction in each layer;
forming an ohmic contact to each of the n-type regions; and
forming an ohmic contact to a common p-type layer.

9. A method as claimed in claim 8, wherein the step of etching the body exposes a plurality of portions within each layer at spaced locations across the body, to form a plurality of multi-wavelength detectors.

10. A method as claimed in claim 8, wherein the method further includes the step of etching a channel between adjacent detectors.

11. A method as claimed in claim 10, wherein said channel passes through all of the p-type layers except the common p-type layer.

12. A method for forming an array of n-p junctions on a semiconductor body having a plurality of p-type material layers containing Group II and Group VI elements, one of which is mercury, comprising the steps of:
etching the body to expose a portion of each layer;
forming a passivation layer over the body;
forming a window in the passivation layer;
subjecting the body to a reactive ion etching process to form n-p junctions that extend substantially to the substrate;
forming an ohmic contact to each of the common n-type regions; and
forming ohmic contacts to each layer on said portions.

13. A method as claimed in claim 12, wherein the step of etching the body exposes a plurality of portions of each layer at spaced locations across the body to form a plurality of detectors.

14. A method as claimed in claim 12, wherein adjacent detectors are separated by an n-p junction.

15. A semiconductor body comprising an array of n-p junctions formed thereon in accordance with the method as claimed in claim 8.

16. A semiconductor material comprising an n-p junction, wherein the semiconductor material includes:
a substrate;
a layer of p-type material surmounting said substrate;
a region of converted n-type material formed on a localised portion of the surface of said p-type material, defining an n-p junction between the p-type and n-type material; and
a passivation layer surmounting the surface of the p-type material and the n-p junction, including windows respectively exposing part of the surface of the converted n-type material and a portion of the surface of the p-type material distant from the n-type material for disposing ohmic contacts on the respectively exposed surfaces, without exposing the n-p junction;
wherein a region of said p-type material is converted to n-type to form said region of converted n-type material using reactive-ion etching.

17. A semiconductor material as claimed in claim 16, wherein the semiconductor material further includes ohmic contacts so as to form an electronically connectable component.

18. A semiconductor material as claimed in claim 16, wherein the p-type material is mercury cadmium telluride.

19. A semiconductor material as claimed in claim 16, wherein the conversion is performed via a plasma induced process.

20. A semiconductor material as claimed in claim 19, wherein the plasma induced process is a reactive ion etching process that creates a laterally displaced n-on-p junction beneath the surface of the passivation layer, without degrading the passivation layer.

21. A semiconductor material as claimed in claim 16, wherein the passivation layer is formed of zinc sulphide.

22. A semiconductor material as claimed in claim 16, wherein the passivation layer has a thickness of 0.3 μm.

23. A semiconductor material as claimed in claim 16 wherein the material further includes a layer of n-type material interposed between said substrate and said layer of p-type material, such that said p-type layer surmounts said n-type layer, and said n-type layer surmounts said substrate to form a junction isolated n-on-p diode.

24. A semiconductor material as claimed in claim 23, wherein the region of n-type material extends through said p-type layer to said n-type layer.

25. A semiconductor material as claimed in claim 24, wherein said region of n-type material is annular, and is arranged to circumscribe a portion of said layer of p-type material so as to isolate the circumscribed portion from the remainder of said layer of p-type material.

26. A semiconductor material as claimed in claim 25, wherein a plurality of discrete regions of n-type material are provided in the layer of p-type material to form an array of n-p junctions therein, whereby a window is disposed to expose a portion of the circumscribed portion of p-type material for disposing an ohmic contact thereon.

27. A semiconductor material as claimed in claim 16, wherein a multi-wavelength detector is formed by:
interposing between the layer of p-type material and the passivation layer:
i. an isolating layer of p-type material;
ii. a second layer of p-type material; and
iii. another isolating layer of p-type material;
whereby the isolating layer surmounts the first layer of p-type material, the second layer surmounts the isolating layer, the other isolating layer surmounts the third layer, and the passivation layer surmounts the other isolating layer.

28. A semiconductor material as claimed in claim 27, wherein the semiconductor further includes a third layer, and a further isolating layer is interposed between the other isolating layer and the passivation layer in an accumulative manner, allowing the formation of additional wavelength detectors.

29. A semiconductor material as claimed in claim 27, wherein the layers of p-type material are each formed of a thickness corresponding to a predetermined cut-off wavelength.

30. A semiconductor material as claimed in claim 27, wherein the semiconductor material is arranged such that incident light impinges on the substrate side.

31. A semiconductor material arranged as claimed in claim 30, wherein the thickness of each layer is such that the cut-off wavelength of the first layer is less than the second layer, and the second layer is less than any third layer, in like manner for any subsequent layers.

32. A semiconductor material as claimed in claim 27, wherein the isolating layers are formed of semiconductor material having a wider band gap than the semiconductor material used for forming the p-type layers.

33. A semiconductor material as claimed in claim 27, wherein the p-type layers and their surmounting isolating layers are arranged in pairs, such pairs being recessed in order that a portion of each corresponding p-type layer and isolating layer pair constitutes the final layer pair of that portion of the semiconductor material and is surmounted by said passivation layer.

34. A semiconductor material as claimed in claim 33, wherein a converted n-type region is formed in each final layer pair, such region extending through the isolating layer to the layer of p-type material; and windows being provided in the passivation layer of each final layer pair in order to expose part of each converted n-type region for disposing ohmic contacts thereon.

35. A semiconductor material as claimed in claim 34, wherein a channel is formed extending through the outer layers of p-type material and the isolating material such that the passivation layer directly surmounts the first isolating layer at prescribed locations on the semiconductor material to divide the material into predetermined detector elements or pixels to constitute an array.

36. A semiconductor material as claimed in claim 33, wherein a converted n-type region is formed in each final layer pair, such region comprising:
the first p-type layer and the corresponding surmounting isolating layer thereof; and
the last p-type layer and the corresponding surmounting isolating layer thereof;
whereby the converted n-type region extends through to the substrate, and windows are provided in the passivation layer of:
i. the first and last final layer pairs to expose part of each converted n-type region; and
ii. each final layer pair distant from the converted n-type region to expose part of the isolating layer in order to dispose the ohmic contacts on the exposed parts of the semiconductor material.

37. A semiconductor material as claimed in claim 36, wherein the converted n-type regions divide the semiconductor material into predetermined detector elements or pixels in order to constitute an array.

38. A semiconductor material as claimed in claim 34, wherein each detector element comprises a single final layer pair from each of the layers constituting the semiconductor material, whereby each final layer pair is adjacent to another layer pair within the detector element.

39. (canceled)

40. (canceled)

41. (canceled)

42. (canceled)

43. A method for converting the type of a region of a p-type body to form an n-p junction, comprising reactive ion etching a portion of the surface of a p-type body for a prescribed time period at a prescribed pressure, progressively converting the underlying p-type of the body to n-type to a depth determined by said time period and said pressure.

44. A method as claimed in claim 39, including mounting the p-type body on a cathode of a parallel plate reactor and applying a hydrogen flow rate of 27 sccm.

45. A method as claimed in claim 39, including mounting the p-type body on a cathode of a parallel plate reactor and applying a methane flow rate of 5 sccm.

46. A method as claimed in claim 39, including mounting the p-type body on a cathode of a parallel plate reactor and applying a total pressure of 412 mTorr.

47. A method as claimed in claim 39, including mounting the p-type body on a cathode of a parallel plate reactor and applying a DC bias of 200V.

48. A method as claimed in claim 39, including mounting the p-type body on a cathode of a parallel plate reactor and applying a cathode temperature of 18° C.

49. A method as claimed in claim 39, wherein said prescribed time period is 2 minutes to produce a depth of approximately 3μ.
